(19) United States
(12) Patent Application Publication
(10) Pub. No.: US 2026/0068395 A1
(43) Pub. Date: Mar. 5, 2026

(54) ANTI-REFLECTIVE FILM AND DISPLAY DEVICE INCLUDING THE SAME

(71) Applicant: Samsung Display Co., LTD., Yongin-si (KR)

(72) Inventors: Sang Hyun SONG, Yongin-si (KR); Joon Hyung KIM, Yongin-si (KR)

(73) Assignee: Samsung Display Co., LTD., Yongin-si (KR)

(21) Appl. No.: 19/199,992

(22) Filed: May 6, 2025

(30) Foreign Application Priority Data
Sep. 3, 2024 (KR) 10-2024-0119209

(51) Int. Cl. H10H 29/80; G06F 1/16; H10K 59/80; H10K 77/10

(52) U.S. Cl. CPC H10H 29/842; G06F 1/1652; H10K 59/87; H10K 59/879; H10K 77/111

(57) ABSTRACT

Provided is an anti-reflective film including a protective member, a refractive member disposed on a surface of the protective member, and a shock absorbing member disposed between the protective member and the refractive member. The refractive member includes a first refractive layer and a second refractive layer, the first refractive layer is disposed on the shock absorbing member, and the second refractive layer is disposed on the first refractive layer.

### CROSS-REFERENCE TO RELATED APPLICATION(S)

This application claims priority to and benefits of Korean Patent Application No. 10-2024-0119209 under 35 U.S.C. § 119, filed on Sep. 3, 2024, in the Korean Intellectual Property Office, the entire contents of which are incorporated herein by reference.

### BACKGROUND

### 1. Technical Field

The disclosure relates to an anti-reflective film and a display device including the anti-reflective film.

### 2. Description of the Related Art

As an information society develops, the demand for a display device for displaying an image is increasing in various forms. For example, the display device is applied to various electronic devices, such as smartphones, digital cameras, laptop computers, navigation devices, and smart televisions.

In order to increase the portability of display devices and provide a wider display screen, a bendable display device with a bendable display area or a foldable display device with a foldable display area has recently been released.

Meanwhile, in case that the display device is exposed to external light such as various lights and natural light, an image internally created may not be clearly conveyed to a user due to reflected light, or the user's eyes may become tired. For this reason, the demand for anti-reflection is increasing.

### SUMMARY

Aspects of the disclosure provide an anti-reflective film that may be prevented from being damaged even in case that a display device is folded, and a display device including the same.

However, aspects of the disclosure are not restricted to those set forth herein. The above and other aspects of the disclosure will become more apparent to one of ordinary skill in the art to which the disclosure pertains by referencing the detailed description of the disclosure given below.

According to an aspect of the disclosure, an anti-reflective film includes a protective member, a refractive member disposed on a surface of the protective member, and a shock absorbing member disposed between the protective member and the refractive member.

The refractive member includes a first refractive layer and a second refractive layer, the first refractive layer is disposed on the shock absorbing member, and the second refractive layer is disposed on the first refractive layer.

The first refractive layer has a higher refractive index than the second refractive layer.

The refractive member includes a first refractive layer and a second refractive layer, and the first refractive layer and the second refractive layer are provided in plural and are alternately stacked.

One of the plurality of second refractive layers is disposed on the shock absorbing member, and another of the plurality of second refractive layers is disposed at an uppermost end of the refractive member.

Thicknesses of the first refractive layer disposed at an uppermost end among the plurality of first refractive layers and the second refractive layer disposed at an uppermost end among the plurality of second refractive layers are substantially the same as each other.

A thickness of a first refractive layer disposed at an uppermost end among the plurality of first refractive layers is thicker than thicknesses of other first refractive layers, and a thickness of a second refractive layer disposed at an uppermost end among the plurality of second refractive layers is thicker than thicknesses of other second refractive layers.

The first refractive layer has a higher refractive index than the second refractive layer.

A thickness of the shock absorbing member is thinner than thicknesses of the protective member and the refractive member.

The shock absorbing member includes at least one of polyethylene terephthalate (PET), acrylate, and urethane acrylate.

The protective member includes a first protective layer, a second protective layer, and a shock absorbing layer, and the shock absorbing layer is disposed between the first protective layer and the second protective layer.

A thickness of the shock absorbing layer is thinner than thicknesses of the first protective layer and the second protective layer.

A thickness of the shock absorbing layer is thinner than a thickness of the shock absorbing member.

The shock absorbing layer includes at least one of polyethylene terephthalate (PET), acrylate, and urethane acrylate.

According to an aspect of the disclosure, a display device includes a display panel, a window member disposed on the display panel, and an anti-reflective film disposed on a surface of the window member, wherein the anti-reflective film includes a protective member disposed on the surface of the window member, a refractive member disposed on a surface of the protective member, and a shock absorbing member disposed between the protective member and the refractive member.

The refractive member includes a first refractive layer and a second refractive layer, the first refractive layer is disposed on the shock absorbing member, and the second refractive layer is disposed on the first refractive layer.

The first refractive layer has a higher refractive index than the second refractive layer.

The refractive member includes a first refractive layer and a second refractive layer, and the first refractive layer and the second refractive layer are provided in plural and are alternately stacked.

One of the plurality of second refractive layers is disposed on the shock absorbing member, and another of the plurality of second refractive layers is disposed at an uppermost end of the refractive member.

According to an aspect of the disclosure, an electronic device includes a display panel, a window member disposed on the display panel, and an anti-reflective film disposed on a surface of the window member, wherein the anti-reflective film includes a protective member disposed on the surface of the window member, a refractive member disposed on a surface of the protective member, and a shock absorbing member disposed between the protective member and the refractive member.

According to the anti-reflective film and the display device including the same according to the disclosure, by disposing a shock absorbing member between a protective member and a refractive member, the anti-reflective film may be prevented from being damaged even in case that the display device is folded.

The effects according to the embodiments of the disclosure are not limited to those mentioned above and more various effects are included in the following description of the disclosure.

### BRIEF DESCRIPTION OF THE DRAWINGS

The above and other aspects and features of the disclosure will become more apparent by describing in detail embodiments thereof with reference to the attached drawings, in which:

FIG. 1 is a schematic perspective view illustrating a state in which a display device according to an embodiment is unfolded;

FIG. 2 is a schematic perspective view illustrating a state in which the display device of FIG. 1 is folded;

FIG. 3 is a schematic perspective view illustrating a state in which a display device according to another embodiment is unfolded;

FIG. 4 is a schematic perspective view illustrating a state in which the display device of FIG. 3 is folded;

FIG. 5 is a schematic cross-sectional view illustrating the display device according to an embodiment of the disclosure;

FIG. 6 is a schematic cross-sectional view of a display panel of FIG. 5;

FIGS. 7 and 8 are schematic cross-sectional views illustrating a first embodiment of an anti-reflective film in the display device according to an embodiment of the disclosure;

FIGS. 9 and 10 are schematic cross-sectional views illustrating a second embodiment of the anti-reflective film in the display device according to an embodiment of the disclosure;

FIG. 11 is an enlarged schematic view of part A of FIG. 10;

FIGS. 12 and 13 are schematic cross-sectional views illustrating a third embodiment of the anti-reflective film in the display device according to an embodiment of the disclosure;

FIGS. 14 and 15 are schematic cross-sectional views illustrating a fourth embodiment of the anti-reflective film in the display device according to an embodiment of the disclosure;

FIG. 16 is an enlarged schematic view of part B of FIG. 15;

FIG. 17 is a schematic block diagram of an electronic device according to one embodiment of the disclosure; and

FIG. 18 is a schematic diagram of an electronic device according to various embodiments of the disclosure.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals and/or reference characters denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or”includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

Advantages and features of the disclosure and methods to achieve them will become apparent from the descriptions of embodiments hereinbelow with reference to the accompanying drawings. However, the disclosure is not limited to embodiments disclosed herein but may be implemented in various different ways. The embodiments are provided for making the disclosure of the disclosure thorough and for fully conveying the scope of the disclosure to those skilled in the art. It is to be noted that the scope of the disclosure is defined only by the claims.

As used herein, a phrase “an element A on an element B” refers to that the element A may be disposed directly on the element B and/or the element A may be disposed indirectly on the element B via another element C. Like reference numerals denote like elements throughout the descriptions. The figures, dimensions, ratios, angles, numbers of elements given in the drawings are merely illustrative and are not limiting.

Although terms such as first, second, etc. are used to distinguish arbitrarily between the elements such terms describe, and thus these terms are not necessarily intended to indicate temporal or other prioritization of such elements. These terms are used to merely distinguish one element from another. Accordingly, as used herein, a first element may be a second element within the technical scope of the disclosure.

Features of various embodiments of the disclosure may be combined partially or totally. As will be clearly appreciated by those skilled in the art, technically various interactions and operations are possible. Various embodiments can be practiced individually or in combination.

Hereinafter, embodiments of the disclosure will be described in detail with reference to the accompanying drawings.

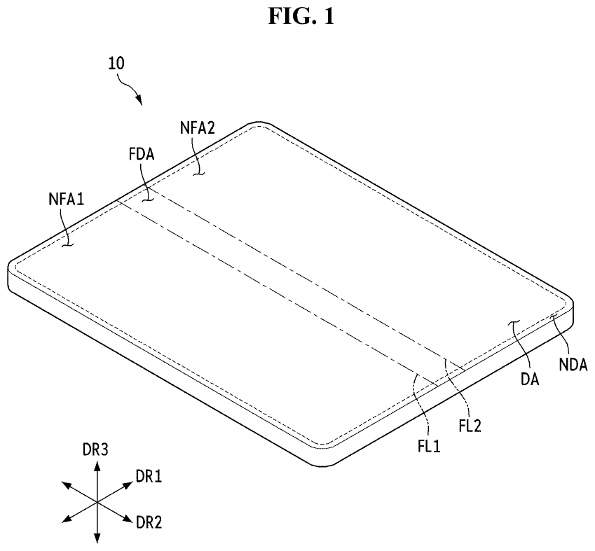

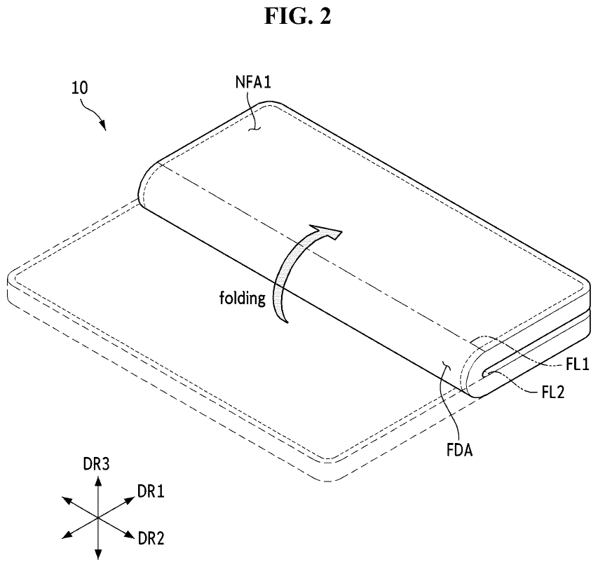

FIG. 1 is a schematic perspective view illustrating a state in which a display device according to an embodiment is unfolded. FIG. 2 is a schematic perspective view illustrating a state in which the display device of FIG. 1 is folded.

Referring to FIGS. 1 and 2, FIG. 1 illustrates a first state of a display device 10 in which the display device 10 is unfolded without being folded at folding lines FL1 and FL2 (e.g., unfolded state), and FIG. 2 illustrates a second state of the display device 10 in which the display device 10 is folded at the folding lines FL1 and FL2 (e.g., folded state).

The display device 10 according to an embodiment is a device that displays a moving image or a still image, and may be used as a display screen of each of various products such as a television, a laptop computer, a monitor, a billboard, and Internet of Things (IOT) as well as portable electronic devices such as a mobile phone, a smartphone, a tablet personal computer (PC), a smartwatch, a watch phone, a mobile communication terminal, an electronic organizer, an electronic book, a portable multimedia player (PMP), a navigation device, and an ultra mobile PC (UMPC).

In FIGS. 1 and 2, a first direction DR1 may be a direction parallel to one side of the display device 10 in a plan view, for example, a horizontal direction of the display device 10. A second direction DR2 may be a direction parallel to another side in contact with one side of the display device 10 in a plan view, and may be a vertical direction of the display device 10. A third direction DR3 may be a thickness direction of the display device 10.

A planar shape of the display device 10 may be a quadrangular shape such as a rectangle. Each corner of the display device 10 may have a right-angled planar shape or a round planar shape. An upper surface (or front surface) of the display device 10 may include two short sides disposed in the first direction DR1 and two long sides disposed in the second direction DR2.

The display device 10 may include a display area DA and a non-display area NDA. A planar shape of the display area DA may follow the shape of the display device 10. For example, in case that the planar shape of the display device 10 is a rectangle, the planar shape of the display area DA may also be a rectangle.

The display area DA may be an area including multiple pixels to display an image. The non-display area NDA may not include the pixels and does not display an image. The non-display area NDA may be disposed around the display area DA. The non-display area NDA may be disposed to surround the display area DA, but the embodiment of the disclosure is not limited thereto. The display area DA may be partially surrounded by the non-display area NDA.

The display device 10 may maintain both a first state in which the display device 10 is unfolded and a second state in which the display device 10 is folded. The display device 10 may be folded in an in-folding manner so that the display areas DA face each other (e.g., folding inward), as illustrated in FIG. 2. For example, the upper surfaces (or front surfaces) of the display device 10 may face each other when folded. For example, the display devices 10 may be folded in an out-folding manner so that the bottom surfaces (or back surfaces) thereof face each other (e.g., folding outward).

The display device 10 may include a folding area FDA, a first non-folding area NFA1, and a second non-folding area NFA2. The folding area FDA may be an area in which the display device 10 is bent or folded, and the first non-folding area NFA1 and the second non-folding area NFA2 may be areas in which the display device 10 is not bent or folded. The first non-folding area NFA1 and the second non-folding area NFA2 may be flat areas of the display device 10.

The first non-folding area NFA1 may be disposed on one side of the folding area FDA, for example, a left side thereof. The second non-folding area NFA2 may be disposed on another side of the folding area FDA, for example, a right side thereof. The folding area FDA is an area defined by the first folding line FL1 and the second folding line FL2 and may be an area in which the display device 10 is bent with a predetermined curvature. The first folding line FL1 may be a boundary between the folding area FDA and the first non-folding area NFA1, and the second folding line FL2 may be a boundary between the folding area FDA and the second non-folding area NFA2.

As illustrated in FIGS. 1 and 2, the first folding line FL1 and the second folding line FL2 may extend in the second direction DR2, and for example, the display device 10 may be folded along the second direction DR2. Accordingly, since a length of the display device 10 in the first direction DR1 may be reduced by approximately half, it may be convenient for a user to carry the display device 10.

In case that the first folding line FL1 and the second folding line FL2 extend in the second direction DR2 as illustrated in FIGS. 1 and 2, a length of the folding area FDA in the second direction DR2 may be longer than a length thereof in the first direction DR1. A length of the first non-folding area NFA1 in the second direction DR2 may be longer than a length of the first non-folding area NFA1 in the first direction DR1. A length of the second non-folding area NFA2 in the second direction DR2 may be longer than a length of the second non-folding area NFA2 in the first direction DR1.

Each of the display area DA and the non-display area NDA may overlap at least one of the folding area FDA, the first non-folding area NFA1, and the second non-folding area NFA2. As illustrated in FIGS. 1 and 2, each of the display area DA and the non-display area NDA overlaps the folding area FDA, the first non-folding area NFA1, and the second non-folding area NFA2.

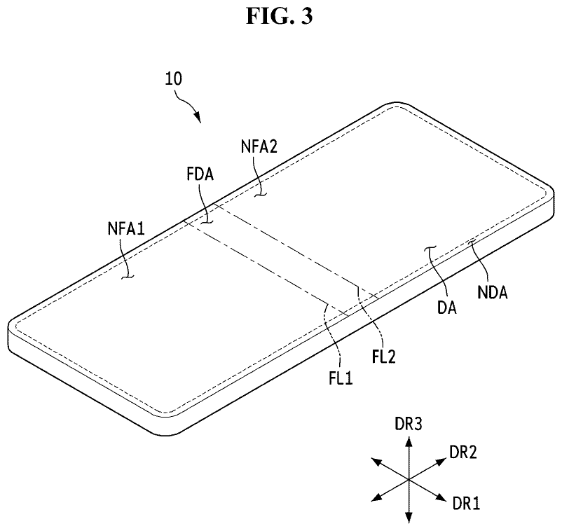

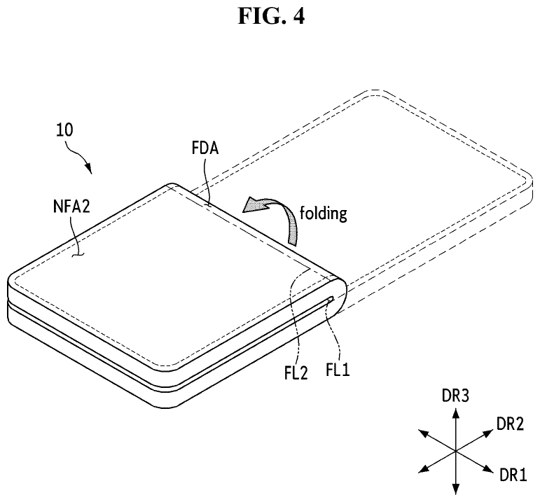

FIG. 3 is a schematic perspective view illustrating a state in which a display device according to another embodiment is unfolded. FIG. 4 is a schematic perspective view illustrating a state in which the display device of FIG. 3 is folded.

The embodiment of FIGS. 3 and 4 is different from the embodiment of FIGS. 1 and 2 only in that the length of the display device 10 in the second direction DR2 is reduced by approximately half because the first folding line FL1 and the second folding line FL2 extend in the first direction DR1 and the display device 10 is folded in the second direction DR2. Therefore, in FIGS. 3 and 4, the descriptions that overlap the embodiment of FIGS. 1 and 2 will be omitted.

Referring to FIGS. 3 and 4, FIG. 3 illustrates a first state of a display device 10 in which the display device 10 is unfolded without being folded at folding lines FL1 and FL2, and FIG. 4 illustrates a second state of the display device 10 in which the display device 10 is folded at the folding lines FL1 and FL2.

In the first state in which the display device 10 is unfolded, the long side of the display device 10 may extend along the second direction DR2, and the short side of the display device 10 may extend along the first direction DR1.

As illustrated in FIGS. 3 and 4, the first folding line FL1 and the second folding line FL2 may extend in the first direction DR1, and for example, the display device 10 may be folded along the second direction DR2.

The first non-folding area NFA1 may be disposed on one side of the folding area FDA, for example, a lower side thereof. The second non-folding area NFA2 may be disposed on another side of the folding area FDA, for example, an upper side thereof.

In case that the first folding line FL1 and the second folding line FL2 extend in the first direction DR1 as illustrated in FIGS. 3 and 4, a length of the folding area FDA in the first direction DR1 may be longer than a length thereof in the second direction DR2. A length of the first non-folding area NFA1 in the second direction DR2 may be longer than a length of the first non-folding area NFA1 in the first direction DR1. A length of the second non-folding area NFA2 in the second direction DR2 may be longer than a length of the second non-folding area NFA2 in the first direction DR1.

Hereinafter, for convenience of explanation, the embodiment of FIGS. 3 and 4 will be used as an example, but the disclosure is not limited thereto, and the following may also be equally applied to the embodiment of FIGS. 1 and 2.

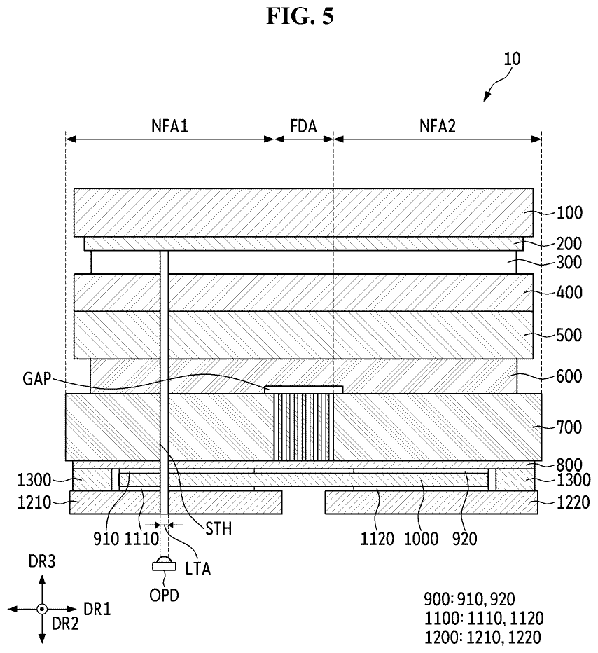

FIG. 5 is a schematic cross-sectional view illustrating the display device according to an embodiment of the disclosure.

Referring to FIG. 5, the display device 10 according to an embodiment may include an anti-reflective film 100, a window member 200, a first adhesive member 300, an upper protective member 400, a display panel 500, a lower protective member 600, a panel support member 700, a buffer member 800, a second adhesive member 900, a lower functional member 1000, a third adhesive member 1100, a metal support member 1200, and a permeation prevention member 1300.

Firstly, the display panel 500 may be a panel that displays an image. The display panel 500 may be an organic light emitting display panel including an organic light emitting layer, a quantum dot light emitting display panel including a quantum dot light emitting layer, an inorganic light emitting display panel that uses an inorganic semiconductor element as a light emitting element, and a micro light emitting display panel that uses a micro light emitting diode as a light emitting element. Hereinafter, the display panel 500 is described as an organic light emitting display panel, but the disclosure is not limited thereto.

The display panel 500 may include a light transmissive area LTA that overlaps an optical device OPD in the third direction DR3. The optical device OPD is an optical sensor that detects light, and may be, for example, a camera sensor, a proximity sensor, and a luminance sensor. The light transmissive area LTA may be a portion of the display area DA.

The light transmissive area LTA may include a transmissive area capable of transmitting light. For example, the light transmissive area LTA may be a through hole that penetrates through the display panel. A light transmittance of the light transmissive area LTA may be higher than the light transmittance of the display area DA excluding the light transmissive area LTA. Due to the transmissive area of the light transmissive area LTA, the density or integration of pixels in the light transmissive area LTA may be lower than the density or integration of pixels in the display area DA excluding the light transmissive area LTA. For example, the number of pixels per unit area in the light transmissive area LTA may be smaller than the number of pixels per unit area in the display area DA excluding the light transmissive area LTA. For example, pixels per inch (PPI) in the light transmissive area LTA may be smaller than PPI in the display area DA excluding the light transmissive area LTA.

The upper protective member 400 may be disposed on the upper surface (or front surface) of the display panel 500. The upper protective member 400 may perform a shock absorbing function for protecting the display panel 500 from external shock (or force). For example, the upper protective member 400 may include a material having high flexibility and high rigidity.

The window member 200 may be attached to the upper surface (or front surface) of the upper protective member 400 using the first adhesive member 300. The window member 200 is made of a transparent material, and may be, for example, glass or plastic. For example, the window member 200 may be an ultra-thin glass (UTG) or a transparent polyimide film having a thickness of about 0.1 mm or less.

The first adhesive member 300 may be a transparent adhesive film or a transparent adhesive resin. For example, the first adhesive member 300 may include a transparent adhesive such as pressure sensitive adhesive (PSA) or optically clear adhesive (OCA). The first adhesive member 300 may include an acrylic adhesive material.

The anti-reflective film 100 may be disposed on the upper surface (or front surface) of the window member 200. The anti-reflective film 100 may include multiple refractive layers having different refractive indices. The anti-reflective film 100 may reduce reflected light through multiple refractive layers. Since the anti-reflective film 100 is a main feature of the disclosure, a detailed description thereof will be provided later.

The lower protective member 600 may be disposed on a bottom surface (or back surface) of the display panel 500. The lower protective member 600 may serve to support the display panel 500 and protect the bottom surface (or back surface) of the display panel 500. The lower protective member 600 may be made of plastic such as polyethylene terephthalate (PET) or polyimide.

In order to allow the display device 10 to smoothly fold, at least a portion of the lower protective member 600 may be removed from the folding area FDA of the display device 10. For example, as illustrated in FIG. 5, the lower protective member 600 may include a gap GAP disposed in the folding area FDA.

The gap GAP may be disposed adjacent to an upper surface of the panel support member 700. In the display device 10 according to the embodiment, as the lower protective member 600 includes the gap GAP, the panel support member 700 having high rigidity and the lower protective member 600 may be prevented from being in direct contact with each other in the folding area FDA. Accordingly, folding stress of the display device 10 may be reduced.

The panel support member 700 may be disposed on a bottom surface (or back surface) of the lower protective member 600. The panel support member 700 may be a rigid member whose shape or volume is not readily changed by pressure (or force) from the outside. Since the panel support member 700 is disposed on the rear surface of the display panel 500 and is the rigid member whose shape or volume is not readily changed due to the pressure (or force) from the outside, the panel support member 700 may support the display panel 500.

The panel support member 700 may be a metal plate. For example, the panel support member 700 is a metal plate and may be made of metal or a metal alloy. The panel support member 700 may include, but is not limited to, copper (Cu), aluminum (Al), stainless steel (SUS), and/or an alloy thereof.

In another embodiment, the panel support member 700 may be formed of a polymer including carbon fiber or glass fiber. For example, since the panel support member 700 is formed of the polymer including carbon fiber or glass fiber, the panel support member 700 may pass electromagnetic signals of a digitizer member in case that the display device 10 includes the digitizer member. Therefore, the panel support member 700 capable of supporting the display panel 500 while not lowering a touch sensitivity of the digitizer member may be provided.

The panel support member 700 may include a through hole STH that overlaps the optical device OPD in the third direction DR3. The through hole STH may overlap the light transmissive area LTA of the display panel 500 in the third direction DR3. An area of the through hole STH may be greater than or equal to an area of the light transmissive area LTA. The optical device OPD may detect light incident from the upper surface (or front surface) of the display device 10 through the light transmissive area LTA and the through hole STH.

The panel support member 700 may include a folding portion so as to be readily bent in the folding area FDA. As the panel support member 700 includes the folding portion disposed in the folding area FDA, the panel support member 700 may be readily bent in case that the display device 10 is folded.

The buffer member 800 may reduce the folding stress of the panel support member 700 having high rigidity in case that the display device 10 is folded. The buffer member 800 may include a material having high elasticity capable of absorbing external shock (or force). For example, the buffer member 800 may include, but is not limited to, thermoplastic polyurethane (TPU).

In some embodiments, although not illustrated in the drawings, the display device 10 may further include a digitizer member (not illustrated). The digitizer member (not illustrated) may be disposed on a bottom surface (or back surface) of the buffer member 800. The digitizer member (not illustrated) may include electrode patterns for sensing approach or contact of an electronic pen such as a stylus pen supporting electromagnetic resonance (EMR). The digitizer member (not illustrated) may sense a magnetic field or electromagnetic signal emitted from the electronic pen based on the electrode patterns, and may determine a point where the sensed magnetic field or electromagnetic signal is greatest as a touch coordinate.

A magnetic metal powder may be disposed on a bottom surface (or back surface) of the digitizer member (not illustrated). For example, the magnetic field or electromagnetic signal passing through the digitizer (not illustrated) may flow into the interior of the magnetic metal powder. Therefore, the magnetic metal powder may reduce the magnetic field or electromagnetic signal of the digitizer member (not illustrated) from being emitted to the bottom surface (or back surface) of the display device 10.

The lower functional member 1000 may be attached to the bottom surface (or back surface) of the buffer member 800 by the second adhesive member 900. The lower functional member 1000 may include at least one of a light blocking layer for absorbing light incident from the outside, a buffer layer for absorbing external shock (or force) from the outside, and a heat dissipation layer for efficiently dissipating heat of the display panel 500.

The light blocking layer may block transmission of light, thereby preventing the components disposed below the light blocking layer from being viewed from the upper portion of the display panel 500. The light blocking layer may include a light absorbing material such as a black pigment or a black dye.

The buffer layer may absorb external shock (or force) to prevent the display panel 500 from being damaged. The buffer layer may be formed as a single layer or multiple layers. For example, the buffer layer may be formed of a polymer resin such as polyurethane, polycarbonate, polypropylene, or polyethylene, or may include a material having elasticity, such as a sponge made by foaming and molding rubber, urethane-based materials, or acrylic-based materials.

The heat dissipation layer may include a first heat dissipation layer including graphite or carbon nano-tube, and a second heat dissipation layer formed of a metal thin film with excellent thermal conductivity such as copper, nickel, ferrite, and silver.

The second adhesive member 900 may be a transparent adhesive film or a transparent adhesive resin. For example, the second adhesive member 900 may include a transparent adhesive such as pressure sensitive adhesive (PSA) or optically clear adhesive (OCA). The second adhesive member 900 may include an acrylic adhesive material.

The second adhesive member 900 may not be disposed in the folding area FDA of the display device 10 so that the display device 10 is smoothly folded. For example, the second adhesive member 900 may include a second_first adhesive member 910 disposed in the first non-folding area NFA1 and a second_second adhesive member 920 disposed in the second non-folding area NFA2. The second_first adhesive member 910 and the second_second adhesive member 920 may be disposed to be spaced apart from each other with respect to the folding area FDA interposed therebetween.

The metal support member 1200 may be attached to a bottom surface (or back surface) of the lower functional member 1000 by the third adhesive member 1100. The metal support member 1200 may include a material having high rigidity to support the lower functional member 1000. For example, the metal support member 1200 may include, but is not limited to, stainless steel such as SUS316.

The metal support member 1200 may not be disposed in the folding area FDA of the display device 10 so that the display device 10 is smoothly folded. For example, the metal support member 1200 may include a first metal support member 1210 disposed in the first non-folding area NFA1 and a second metal support member 1220 disposed in the second non-folding area NFA2. The first metal support member 1210 and the second metal support member 1220 may be disposed to be spaced apart from each other with respect to the folding area FDA interposed therebetween.

The third adhesive member 1100 may be a transparent adhesive film or a transparent adhesive resin. For example, the third adhesive member 1100 may include a transparent adhesive such as pressure sensitive adhesive (PSA) or optically clear adhesive (OCA). The third adhesive member 1100 may include an acrylic adhesive material.

The third adhesive member 1100 may not be disposed in the folding area FDA of the display device 10 so that the display device 10 is smoothly folded. For example, the third adhesive member 1100 may include a third_first adhesive member 1110 disposed in the first non-folding area NFA1 and a third_second adhesive member 1120 disposed in the second non-folding area NFA2. The third_first adhesive member 1110 and the third_second adhesive member 1120 may be disposed to be spaced apart from each other with respect to the folding area FDA interposed therebetween.

The permeation prevention member 1300 may be disposed on the bottom surface (or back surface) of the buffer member 800. The permeation prevention member 1300 may be disposed between the buffer member 800 and the metal support member 1200 in the third direction DR3.

The permeation prevention member 1300 may be disposed at an edge of the buffer member 800. The permeation prevention member 1300 may be disposed on one side of the lower functional member 1000. In FIG. 5, the permeation prevention member 1300 is illustrated as being disposed only at the edge of the buffer member 800 or on one side of the lower functional member 1000 in the first direction DR1, but is not limited thereto. For example, the permeation prevention member 1300 may be disposed to surround the lower functional member 1000 on a plane along the first direction DR1 and the second direction DR2.

The permeation prevention member 1300 may be a waterproof (or dustproof) tape or a waterproof (or dustproof) member that is attached to the bottom surface (or back surface) of the buffer member 800 and the upper surface (or front surface) of the metal support member 1200. As a result, the permeation prevention member 1300 may prevent moisture or dust from permeating into the display device 10. For example, the display device 10 that is waterproof and dustproof may be provided.

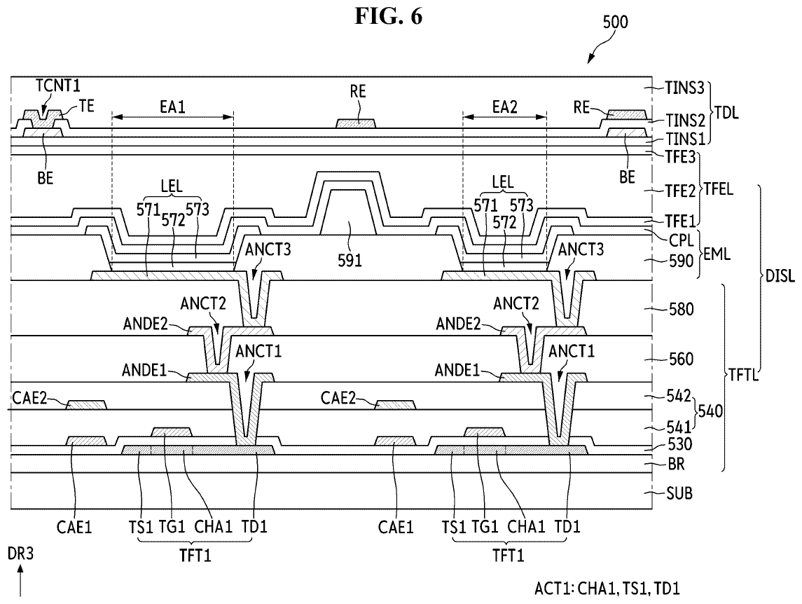

FIG. 6 is a schematic cross-sectional view of a display panel of FIG. 5.

Referring to FIG. 6, the display panel 500 may include a substrate SUB, a display layer DISL disposed on the substrate SUB, and a touch sensing layer TDL disposed on the display layer DISL. The display layer DISL may include a thin film transistor layer TFTL, a light emitting element layer EML, and an encapsulation layer TFEL.

The thin film transistor layer TFTL may be disposed on the substrate SUB. The thin film transistor layer TFTL may include a barrier film BR, a thin film transistor TFT1, a first capacitor electrode CAE1, a second capacitor electrode CAE2, a first anode connection electrode ANDE1, a second anode connection electrode ANDE2, a gate insulating film 530, an insulating film 540 including a first interlayer insulating film 541 and a second interlayer insulating film 542, a first planarization film 560, and a second planarization film 580.

The substrate SUB may be made of an insulating material such as a polymer resin. For example, the substrate SUB may be made of polyimide. The substrate SUB may be a flexible substrate that may be bent, folded, rolled, or the like.

A barrier film BR may be disposed on the substrate SUB. The barrier film BR may protect thin film transistors of the thin film transistor layer TFTL and a light emitting layer 572 of the light emitting element layer EML from moisture permeating through the substrate SUB vulnerable to moisture permeation. The barrier film BR may include multiple inorganic films alternately stacked. For example, the barrier film BR may be formed as a multi-film in which one or more inorganic films of a silicon nitride layer, a silicon oxynitride layer, a silicon oxide layer, a titanium oxide layer, and an aluminum oxide layer are alternately stacked.

The thin film transistor TFT1 may be disposed on the barrier film BR. An active layer ACT1 of the thin film transistor TFT1 may be disposed on the barrier film BR. The active layer ACT1 of the thin film transistor TFT1 may include polycrystalline silicon, single crystal silicon, low-temperature polycrystalline silicon, amorphous silicon, or an oxide semiconductor.

The active layer ACT1 may include a channel region CHA1, a source region TS1, and a drain region TD1. The channel region CHA1 may be a region overlapping a gate electrode TG1 in the third direction DR3 that is a thickness direction of the substrate SUB. The source region TS1 may be disposed on one side of the channel region CHA1, and the drain region TD1 may be disposed on another side of the channel region CHA1. The source region TS1 and the drain region TD1 may be regions that do not overlap the gate electrode TG1 in the third direction DR3. The source region TS1 and the drain region TD1 may be regions having conductivity by doping a silicon semiconductor or an oxide semiconductor with ions or impurities.

The gate insulating film 530 may be disposed on the active layer ACT1 of the thin film transistor TFT1. The gate insulating film 530 may be formed as an inorganic film, for example, a silicon nitride layer, a silicon oxynitride layer, a silicon oxide layer, a titanium oxide layer, or an aluminum oxide layer.

The gate electrode TG1 of the thin film transistor TFT1 and the first capacitor electrode CAE1 may be disposed on the gate insulating film 530. The gate electrode TG1 may overlap the channel region CHA1 in the third direction DR3. It is illustrated in FIG. 6 that the gate electrode TG1 and the first capacitor electrode CAE1 are disposed to be spaced apart from each other, but the gate electrode TG1 and the first capacitor electrode CAE1 may be electrically connected to each other and integrally formed. The gate electrode TG1 and the first capacitor electrode CAE1 may be formed as a single layer or a multi-layer made of any one of molybdenum (Mo), aluminum (Al), chromium (Cr), gold (Au), titanium (Ti), nickel (Ni), neodymium (Nd), and copper (Cu), or an alloy thereof.

The first interlayer insulating film 541 may be disposed on the gate insulating film 530 to cover the gate electrode TG1 of the thin film transistor TFT1 and the first capacitor electrode CAE1. The first interlayer insulating film 541 may be formed as an inorganic film, for example, a silicon nitride layer, a silicon oxynitride layer, a silicon oxide layer, a titanium oxide layer, or an aluminum oxide layer. The first interlayer insulating film 541 may be formed as multiple inorganic films.

The second capacitor electrode CAE2 may be disposed on the first interlayer insulating film 541. The second capacitor electrode CAE2 may overlap the first capacitor electrode CAE1 of the thin film transistor TFT1 in the third direction DR3. In case that the gate electrode TG1 and the first capacitor electrode CAE1 are integrally formed, the second capacitor electrode CAE2 may overlap the gate electrode TG1 in the third direction DR3. Since the first interlayer insulating film 541 has a predetermined dielectric constant, a capacitor may be formed by the first capacitor electrode CAE1, the second capacitor electrode CAE2, and the first interlayer insulating film 541 disposed between the first capacitor electrode CAE1 and the second capacitor electrode CAE2. The second capacitor electrode CAE2 may be formed as a single layer or a multi-layer made of any one of molybdenum (Mo), aluminum (Al), chromium (Cr), gold (Au), titanium (Ti), nickel (Ni), neodymium (Nd), and copper (Cu), or alloys thereof.

The second interlayer insulating film 542 may be disposed on the first interlayer insulating film 541 to cover the second capacitor electrode CAE2. The second interlayer insulating film 542 may be formed as an inorganic film, for example, a silicon nitride layer, a silicon oxynitride layer, a silicon oxide layer, a titanium oxide layer, or an aluminum oxide layer. The second interlayer insulating film 542 may be formed as multiple inorganic films.

A first anode connection electrode ANDE1 may be disposed on the second interlayer insulating film 542. The first anode connection electrode ANDE1 may be electrically connected to the drain region TD1 of the thin film transistor TFT1 through a first connection contact hole ANCT1 penetrating through the gate insulating film 530, the first interlayer insulating film 541, and the second interlayer insulating film 542. The first anode connection electrode ANDE1 may be formed as a single layer or a multi-layer made of any one of molybdenum (Mo), aluminum (Al), chromium (Cr), gold (Au), titanium (Ti), nickel (Ni), neodymium (Nd), and copper (Cu), or an alloy thereof.

The first planarization film 560 for planarizing a step due to the thin film transistor TFT1 may be disposed on the second interlayer insulating film 542 to cover the first anode connection electrode ANDE1. The first planarization film 560 may be formed as an organic film made of an acryl resin, an epoxy resin, a phenolic resin, a polyamide resin, a polyimide resin, or the like.

A second anode connection electrode ANDE2 may be disposed on the first planarization film 560. The second anode connection electrode ANDE2 may be electrically connected to the first anode connection electrode ANDE1 through a second connection contact hole ANCT2 penetrating through the first planarization film 560. The second anode connection electrode ANDE2 may be formed as a single layer or a multi-layer made of any one of molybdenum (Mo), aluminum (Al), chromium (Cr), gold (Au), titanium (Ti), nickel (Ni), neodymium (Nd), and copper (Cu), or an alloy thereof.

The second planarization film 580 may be disposed on the first planarization film 560 to cover the second anode connection electrode ANDE2. The second planarization film 580 may be formed as an organic film made of an acryl resin, an epoxy resin, a phenolic resin, a polyamide resin, a polyimide resin, or the like.

The light emitting element layer EML including light emitting elements LEL and a bank (or pixel defining layer) 590 may be disposed on the second planarization film 580. Each of the light emitting elements LEL includes a pixel electrode 571, a light emitting layer 572, and a common electrode 573.

The pixel electrode 571 may be disposed on the second planarization film 580. The pixel electrode 571 may be electrically connected to the second anode connection electrode ANDE2 through a third connection contact hole ANCT3 penetrating through the second planarization film 580.

In a top emission structure that emits light in a direction of the common electrode 573 with respect to the light emitting layer 572, the pixel electrode 571 may be formed of a metal material having high reflectance, such as a stacked structure (Ti/Al/Ti) of aluminum (Al) and titanium (Ti), a stacked structure (ITO/Al/ITO) of aluminum (Al) and indium tin oxide (ITO), a stacked structure (ITO/Ag/ITO) of silver (Ag) and indium tin oxide (ITO), an APC alloy, and a stacked structure (ITO/APC/ITO) of an APC alloy and ITO. The APC alloy is an alloy of silver (Ag), palladium (Pd), and copper (Cu).

The bank (or pixel defining layer) 590 may be formed to partition the pixel electrode 571 on the second planarization film 580 to define light emitting portions EA1 and EA2. The bank (or pixel defining layer) 590 may be disposed to cover an edge of the pixel electrode 571. The bank (or pixel defining layer) 590 may be formed as an organic film made of an acrylic resin, an epoxy resin, a phenolic resin, a polyamide resin, or a polyimide resin.

Each of a first light emitting portion EA1 and a second light emitting portion EA2 refers to each area in which the pixel electrode 571, the light emitting layer 572, and the common electrode 573 are sequentially stacked and holes from the pixel electrode 571 and electrons from the common electrode 573 are recombined with each other in the light emitting layer 572 to emit light.

The light emitting layer 572 may be disposed on the pixel electrode 571 and the bank (or pixel defining layer) 590. The light emitting layer 572 may include an organic material to emit light of a predetermined color. For example, the light emitting layer 572 may include a hole transporting layer, an organic material layer, and an electron transporting layer.

The common electrode 573 may be disposed on the light emitting layer 572. The common electrode 573 may be disposed to cover the light emitting layer 572. The common electrode 573 may be a common layer commonly formed in the first light emitting portion EA1 and the second light emitting portion EA2.

In the top emission structure, the common electrode 573 may be formed of a transparent conductive material (TCO) such as ITO or indium zinc oxide (IZO) capable of transmitting light, or a semi-transmissive conductive material such as magnesium (Mg), silver (Ag), or an alloy of magnesium (Mg) and silver (Ag). In case that the common electrode 573 is formed of the semi-transmissive conductive material, light emitting efficiency may be increased by a micro cavity.

A spacer 591 may be disposed on the bank (or pixel defining layer) 590. The spacer 591 may serve to support a mask during a process of fabricating the light emitting layer 572. The spacer 591 may be formed as an organic film made of an acryl resin, an epoxy resin, a phenolic resin, a polyamide resin, a polyimide resin, or the like.

The display panel 500 may further include a capping layer CPL disposed on the common electrode 573. The capping layer CPL may include an inorganic material. For example, the capping layer CPL may include at least one of silicon nitride, aluminum nitride, zirconium nitride, titanium nitride, hafnium nitride, tantalum nitride, silicon oxide, aluminum oxide, titanium oxide, tin oxide, cerium oxide, and silicon oxynitride.

An encapsulation layer TFEL may be disposed on the capping layer CPL. The encapsulation layer TFEL may include at least one inorganic film to prevent oxygen or moisture from permeating into the light emitting element layer EML. The encapsulation layer TFEL may include at least one organic film to protect the light emitting element layer EML from foreign substances such as dust. For example, the encapsulation layer TFEL may include a first encapsulation inorganic film TFE1, an encapsulation organic film TFE2, and a second encapsulation inorganic film TFE3.

The first encapsulation inorganic film TFE1 may be disposed on the capping layer CPL, the encapsulation organic film TFE2 may be disposed on the first encapsulation inorganic film TFE1, and the second encapsulation inorganic film TFE3 may be disposed on the encapsulation organic film TFE2. The first encapsulation inorganic film TFE1 and the second encapsulation inorganic film TFE3 may be formed as a multi-film in which one or more inorganic films of a silicon nitride layer, a silicon oxynitride layer, a silicon oxide layer, a titanium oxide layer, and an aluminum oxide layer are alternately stacked. The encapsulation organic film TFE2 may be an organic film made of an acrylic resin, an epoxy resin, a phenolic resin, a polyamide resin, or a polyimide resin.

The touch sensing layer TDL may be disposed on the encapsulation layer TFEL. The touch sensing layer TDL includes a first touch insulating film TINS1, a connection electrode BE, a second touch insulating film TINS2, a driving electrode TE, a sensing electrode RE, and a third touch insulating film TINS3.

The first touch insulating film TINS1 may be disposed on the encapsulation layer TFEL. The first touch insulating film TINS1 may be formed as an inorganic film, for example, a silicon nitride layer, a silicon oxynitride layer, a silicon oxide layer, a titanium oxide layer, or an aluminum oxide layer.

The connection electrodes BE may be disposed on the first touch insulating film TINS1. The connection electrode BE may be formed as a single layer or a multi-layer made of any one of molybdenum (Mo), aluminum (Al), chromium (Cr), gold (Au), titanium (Ti), nickel (Ni), neodymium (Nd), and copper (Cu), or an alloy thereof.

The second touch insulating film TINS2 may be disposed on the first touch insulating film TINS1 to cover the connection electrode BE. The second touch insulating film TINS2 may be formed as an inorganic film, for example, a silicon nitride layer, a silicon oxynitride layer, a silicon oxide layer, a titanium oxide layer, or an aluminum oxide layer. For example, the second touch insulating film TINS2 may be formed as an organic film made of an acryl resin, an epoxy resin, a phenolic resin, a polyamide resin, a polyimide resin, or the like.

The driving electrodes TE and the sensing electrodes RE may be disposed on the second touch insulating film TINS2. The driving electrodes TE and the sensing electrodes RE may be formed as a single layer or a multi-layer made of any one of molybdenum (Mo), aluminum (Al), chromium (Cr), gold (Au), titanium (Ti), nickel (Ni), neodymium (Nd), and copper (Cu), or alloys thereof.

The driving electrode TE and the sensing electrode RE may overlap the connection electrode BE in the third direction DR3. The driving electrode TE may be electrically connected to the connection electrode BE through a touch contact hole TCNT1 penetrating through the first touch insulating film TINS1.

The third touch insulating film TINS3 may be disposed on the second touch insulating film TINS2 to cover the driving electrodes TE and the sensing electrodes RE. The third touch insulating film TINS3 may serve to planarize a step formed due to the driving electrodes TE, the sensing electrodes RE, and the connection electrodes BE. The third touch insulating film TINS3 may be formed as an organic film made of an acryl resin, an epoxy resin, a phenolic resin, a polyamide resin, a polyimide resin, or the like.

Hereinafter, various embodiments of the anti-reflective film 100, which is a main feature of the display device 10 according to an embodiment of the disclosure, will be described with reference to the drawings.

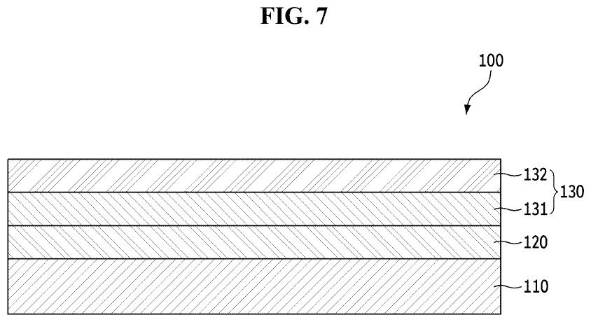

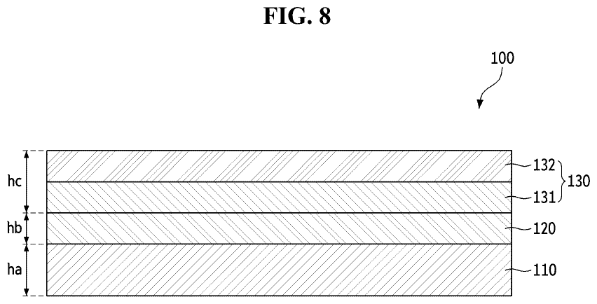

FIGS. 7 and 8 are schematic cross-sectional views illustrating a first embodiment of an anti-reflective film in the display device according to an embodiment of the disclosure.

Referring to FIGS. 7 and 8, an anti-reflective film 100 according to a first embodiment may include a protective member 110, a shock absorbing member 120, and a refractive member 130.

The protective member 110 may be provided as a hard coating layer disposed on the window member 200 (see FIG. 5). The protective member 110 may serve to protect the window member 200 from external shock (or force). The protective member 110 may have a higher strength than the window member 200. The protective member 110 may prevent an occurrence of micro-cracks or shape deformation such as being dented or pressed in the window member 200 due to point shock or surface shock provided from the outside.

The protective member 110 may include at least one of a urethane resin, an epoxy resin, an acrylic resin, and an acrylate resin. The protective member 110 may be disposed on the window member 200 by a coating method. For example, the protective member 110 may be disposed on the window member 200 using a method such as slot die coating, spin coating, etc.

A thickness ha of the protective member 110 may be formed in a thickness range in which a repulsive force against the shape deformed by the display device 10 being folded does not increase.

The shock absorbing member 120 may be disposed on the protective member 110. The shock absorbing member 120 may prevent the protective member 110 from being damaged in case that the display device 10 is folded. In some embodiments, even if a crack occurs in the refractive member 130 due to folding of the display device 10, the shock absorbing member 120 may absorb shock (or force) caused by the crack and prevent the crack from occurring in the protective member 110. A thickness hb of the shock absorbing member 120 may be thinner than the thickness ha of the protective member 110 and a thickness hc of the refractive member 130.

The shock absorbing member 120 may include at least one of polyethylene terephthalate (PET), acrylate, and urethane acrylate. The shock absorbing member 120 may be attached onto the protective member 110 by an adhesive layer (not illustrated). The adhesive layer may include one of a pressure sensitive adhesive (PSA), an optical clear adhesive (OCA), and an optical clear resin (OCR). The shock absorbing member 120 may be disposed on the protective member 110 by a coating method. For example, the shock absorbing member 120 may be disposed on the protective member 110 using a method such as dip coating, slot die coating, or spin coating.

The refractive member 130 may be disposed on the shock absorbing member 120. The refractive member 130 may include a first refractive layer 131 and a second refractive layer 132 having different refractive indices.

The first refractive layer 131 may be disposed on the shock absorbing member 120. The first refractive layer 131 may be disposed on the shock absorbing member 120 by a vacuum deposition method. The first refractive layer 131 may have a higher refractive index than the second refractive layer 132. The refractive index of the first refractive layer 131 may be in a range of about 1.70 to about 2.80, but is not limited thereto. The first refractive layer 131 may have the same thickness as the second refractive layer 132.

The first refractive layer 131 may include a high refractive index oxide. For example, the high refractive index oxide may include at least one of titanium dioxide (TiO₂), zirconium dioxide (ZrO₂), lithium niobate (LiNbO₃), lithium tantalate (LiTaO₃), and lanthanum titanium (LaTiO₂).

The second refractive layer 132 may be disposed on the first refractive layer 131. The second refractive layer 132 may be disposed on the first refractive layer 131 by a vacuum deposition method. The second refractive layer 132 may have a lower refractive index than the first refractive layer 131. The refractive index of the second refractive layer 132 may be in a range of about 1.20 to about 1.50, but is not limited thereto.

The second refractive layer 132 may include a lower refractive index oxide. For example, the low refractive index oxide may include at least one of a silicon resin, silica, and silicon dioxide (SiO₂).

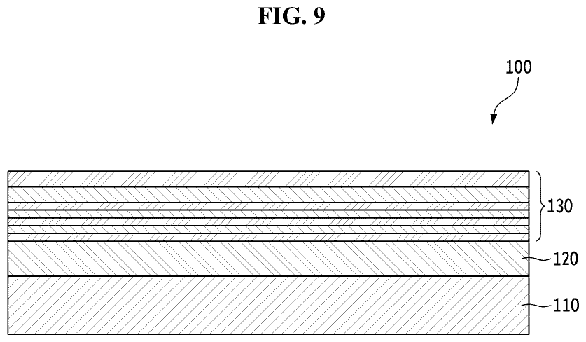

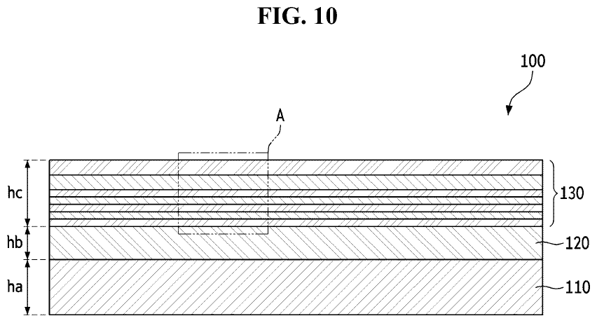

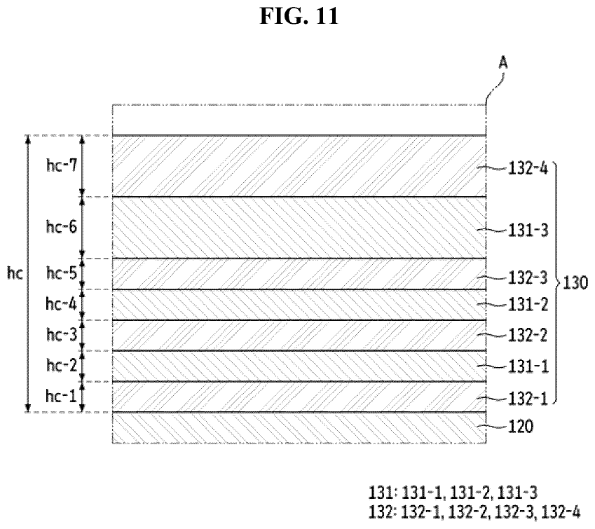

FIGS. 9 and 10 are schematic cross-sectional views illustrating a second embodiment of the anti-reflective film in the display device according to an embodiment of the disclosure. FIG. 11 is an enlarged schematic view of part A of FIG. 10.

Referring to FIGS. 9 to 11, an anti-reflective film 100 according to a second embodiment may include a protective member 110, a shock absorbing member 120, and a refractive member 130.

The protective member 110 may be provided as a hard coating layer disposed on the window member 200 (see FIG. 5). The protective member 110 may serve to protect the window member 200 from external shock (or force). The protective member 110 may have a higher strength than the window member 200. The protective member 110 may prevent an occurrence of micro-cracks or shape deformation such as being dented or pressed in the window member 200 due to point shock or surface shock provided from the outside.

The protective member 110 may include at least one of a urethane resin, an epoxy resin, an acrylic resin, and an acrylate resin. The protective member 110 may be disposed on the window member 200 by a coating method. For example, the protective member 110 may be disposed on the window member 200 using a method such as slot die coating, spin coating, etc.

A thickness ha of the protective member 110 may be formed in a thickness range in which a repulsive force against the shape deformed by the display device 10 being folded does not increase.

The shock absorbing member 120 may be disposed on the protective member 110. The shock absorbing member 120 may prevent the protective member 110 from being damaged in case that the display device 10 is folded. In some embodiments, even if a crack occurs in the refractive member 130 due to folding of the display device 10, the shock absorbing member 120 may absorb shock (or force) caused by the crack and prevent the crack from occurring in the protective member 110. A thickness hb of the shock absorbing member 120 may be thinner than the thickness ha of the protective member 110 and a thickness hc of the refractive member 130.

The shock absorbing member 120 may include at least one of polyethylene terephthalate (PET), acrylate, and urethane acrylate. The shock absorbing member 120 may be attached onto the protective member 110 by an adhesive layer (not illustrated). The adhesive layer may include one of a pressure sensitive adhesive (PSA), an optical clear adhesive (OCA), and an optical clear resin (OCR). The shock absorbing member 120 may be disposed on the protective member 110 by a coating method. For example, the shock absorbing member 120 may be disposed on the protective member 110 using a method such as dip coating, slot die coating, or spin coating.

The refractive member 130 may be disposed on the shock absorbing member 120. The refractive member 130 may include a first refractive layer 131 and a second refractive layer 132 having different refractive indices. The first refractive layer 131 and the second refractive layer 132 may be provided in plural and may be alternately stacked.

The first refractive layer 131 may be disposed on the second refractive layer 132. The first refractive layer 131 may be disposed on the second refractive layer 132 by a vacuum deposition method. The first refractive layer 131 may have a higher refractive index than the second refractive layer 132. The refractive index of the first refractive layer 131 may be in a range of about 1.70 to about 2.80, but is not limited thereto.

The first refractive layer 131 may include a high refractive index oxide. For example, the high refractive index oxide may include at least one of titanium dioxide (TiO₂), zirconium dioxide (ZrO₂), lithium niobate (LiNbO₃), lithium tantalate (LiTaO₃), and lanthanum titanium (LaTiO₂).

The second refractive layer 132 may be disposed on the shock absorbing member 120 or on the first refractive layer 131. The second refractive layer 132 may be disposed on the shock absorbing member 120 or on the first refractive layer 131 by a vacuum deposition method. The second refractive layer 132 may have a lower refractive index than the first refractive layer 131. The refractive index of the second refractive layer 132 may be in a range of about 1.20 to about 1.50, but is not limited thereto.

The second refractive layer 132 may include a lower refractive index oxide. For example, the low refractive index oxide may include at least one of a silicon resin, silica, and silicon dioxide (SiO₂).

It will be described that multiple first refractive layers 131 and second refractive layers 132 are alternately stacked. One of multiple second refractive layers 132 may be disposed on the shock absorbing member 120, and another of multiple second refractive layers 132 may be disposed on the uppermost end of the refractive member 130. Multiple first refractive layers 131 may be disposed between the second refractive layers 132.

For example, the first refractive layer 131 may include a first_first refractive layer 131-1, a first_second refractive layer 131-2, and a first_third refractive layer 131-3, and the second refractive layer 132 may include a second_first refractive layer 132-1, a second_second refractive layer 132-2, a second_third refractive layer 132-3, and a second_fourth refractive layer 132-4.

The second_first refractive layer 132-1 may be disposed on the shock absorbing member 120, and the first_first refractive layer 131-1 may be disposed on the second_first refractive layer 132-1. The second_second refractive layer 132-2 may be disposed on the first_first refractive layer 131-1, and the first_second refractive layer 131-2 may be disposed on the second_second refractive layer 132-2. The second_third refractive layer 132-3 may be disposed on the first_second refractive layer 131-2, and the first_third refractive layer 131-3 may be disposed on the second_third refractive layer 132-3. The second_fourth refractive layer 132-4 may be disposed on the first_third refractive layer 131-3.

A thickness hc-2 of the first_first refractive layer 131-1, a thickness hc-4 of the first_second refractive layer 131-2, a thickness hc-1 of the second_first refractive layer 132-1, a thickness hc-3 of the second_second refractive layer 132-2, and a thickness hc-5 of the second_third refractive layer 132-3 may be the same.

A thickness of the first refractive layer 131 disposed on the uppermost end among multiple first refractive layers 131 and a thickness of the second refractive layer 132 disposed on the uppermost end among multiple second refractive layers 132 may be the same as each other. For example, a thickness hc-6 of the first_third refractive layer 131-3 and a thickness hc-7 of the second_fourth refractive layer 132-4 may be the same.

The thickness of the first refractive layer 131 disposed on the uppermost end among multiple first refractive layers 131 may be thicker than the thicknesses of other first refractive layers 131, and the thickness of the second refractive layer 132 disposed on the uppermost end among multiple second refractive layers 132 may be thicker than the thicknesses of other second refractive layers 132. For example, the thickness hc-6 of the first_third refractive layer 131-3 may be thicker than the thickness hc-2 of the first_first refractive layer 131-1 and the thickness hc-4 of the first_second refractive layer 131-2, and the thickness hc-7 of the second_fourth refractive layer 132-4 may be thicker than the thickness hc-1 of the second_first refractive layer 132-1, the thickness hc-3 of the second_second refractive layer 132-2, and the thickness hc-5 of the second_third refractive layer 132-3.

It is described in the embodiment that the refractive member 130 has three first refractive layers 131 and four second refractive layers 132 alternately stacked, but the disclosure is not limited thereto. The disclosure may include all cases in which one second refractive layer 132 is disposed on the shock absorbing member 120 and another second refractive layer 132 is disposed on the refractive member 130.

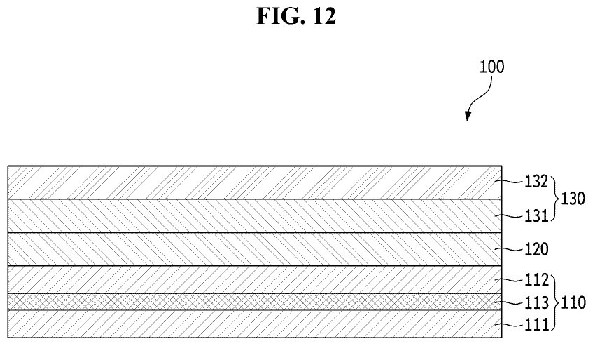

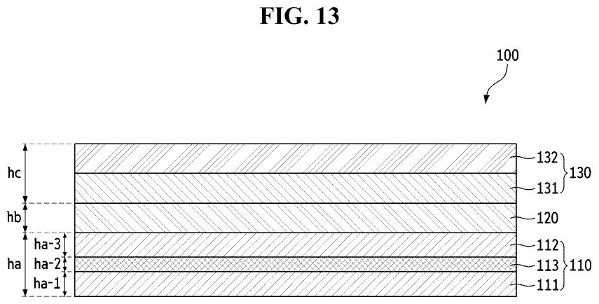

FIGS. 12 and 13 are schematic cross-sectional views illustrating a third embodiment of the anti-reflective film in the display device according to an embodiment of the disclosure.

Referring to FIGS. 12 and 13, an anti-reflective film 100 according to a third embodiment may include a protective member 110, a shock absorbing member 120, and a refractive member 130.

The protective member 110 may be disposed on the window member 200 (see FIG. 5). The protective member 110 may serve to protect the window member 200 from external shock (or force). The protective member 110 may have a higher strength than the window member 200. The protective member 110 may prevent an occurrence of micro-cracks or shape deformation such as being dented or pressed in the window member 200 due to point shock or surface shock provided from the outside. A thickness ha of the protective member 110 may be formed in a thickness range in which a repulsive force against the shape deformed by the display device 10 being folded does not increase.

The protective member 110 may include a first protective layer 111, a second protective layer 112, and a shock absorbing layer 113.

The first protective layer 111 may be provided as a hard coating layer disposed on the window member 200. The first protective layer 111 may include at least one of a urethane resin, an epoxy resin, an acrylic resin, and an acrylate resin. The first protective layer 111 may be disposed on the window member 200 by a coating method. For example, the first protective layer 111 may be disposed on the window member 200 using a method such as slot die coating, spin coating, etc. A thickness ha-1 of the first protective layer 111 may be the same as a thickness ha-3 of the second protective layer 112.

The second protective layer 112 may be provided as a hard coating layer disposed on the first protective layer 111. The second protective layer 112 may be disposed to be spaced apart from the first protective layer 111 in an upward direction so that the shock absorbing layer 113 may be disposed between the second protective layer 112 and the first protective layer 111. The second protective layer 112 may include at least one of a urethane resin, an epoxy resin, an acrylic resin, and an acrylate resin. The second protective layer 112 may be disposed on the shock absorbing layer 113 by a coating method. For example, the second protective layer 112 may be disposed on the shock absorbing layer 113 using a method such as slot die coating, spin coating, etc.

The shock absorbing layer 113 may be disposed between the first protective layer 111 and the second protective layer 112. The shock absorbing layer 113 may prevent the first protective layer 111 from being damaged in case that the display device 10 is folded. In some embodiments, even if a crack occurs in the second protective layer 112 due to folding of the display device 10, the shock absorbing layer 113 may absorb the shock (or force) caused by the crack and prevent the crack from occurring in the first protective layer 111.

The thickness ha-2 of the shock absorbing layer 113 may be thinner than each of the thickness ha-1 of the first protective layer 111 and the thickness ha-3 of the second protective layer 112. The thickness ha-2 of the shock absorbing layer 113 may be thinner than the thickness hb of the shock absorbing member 120.

The shock absorbing layer 113 may include at least one of polyethylene terephthalate (PET), acrylate, and urethane acrylate. The shock absorbing layer 113 may be attached onto the first protective layer 111 by an adhesive layer (not illustrated). The adhesive layer may include one of a pressure sensitive adhesive (PSA), an optical clear adhesive (OCA), and an optical clear resin (OCR). The shock absorbing layer 113 may be disposed on the first protective layer 111 by a coating method. For example, the shock absorbing layer 113 may be disposed on the first protective layer 111 using a method such as dip coating, slot die coating, or spin coating.

The shock absorbing member 120 may be disposed on the second protective layer 112. The shock absorbing member 120 may prevent the protective member 110 from being damaged in case that the display device 10 is folded. In some embodiments, even if a crack occurs in the refractive member 130 due to folding of the display device 10, the shock absorbing member 120 may absorb the shock (or force) caused by the crack and prevent the crack from occurring in the protective member 110. The thickness hb of the shock absorbing member 120 may be thinner than the thickness ha of the protective member 110 and a thickness hc of the refractive member 130.

The shock absorbing member 120 may include at least one of polyethylene terephthalate (PET), acrylate, and urethane acrylate. The shock absorbing member 120 may be attached onto the second protective layer 112 by an adhesive layer (not illustrated). The adhesive layer may include one of a pressure sensitive adhesive (PSA), an optical clear adhesive (OCA), and an optical clear resin (OCR). The shock absorbing member 120 may be disposed on the second protective layer 112 by a coating method. For example, the shock absorbing member 120 may be disposed on the second protective layer 112 using a method such as dip coating, slot die coating, or spin coating.

The refractive member 130 may be disposed on the shock absorbing member 120. The refractive member 130 may include a first refractive layer 131 and a second refractive layer 132 having different refractive indices.

The first refractive layer 131 may be disposed on the shock absorbing member 120. The first refractive layer 131 may be disposed on the shock absorbing member 120 by a vacuum deposition method. The first refractive layer 131 may have a higher refractive index than the second refractive layer 132. The refractive index of the first refractive layer 131 may be 1.70 to 2.80, but is not limited thereto. The first refractive layer 131 may have the same thickness as the second refractive layer 132.

The first refractive layer 131 may include a high refractive index oxide. For example, the high refractive index oxide may include at least one of titanium dioxide (TiO₂), zirconium dioxide (ZrO₂), lithium niobate (LiNbO₃), lithium tantalate (LiTaO₃), and lanthanum titanium (LaTiO₂).

The second refractive layer 132 may be disposed on the first refractive layer 131. The second refractive layer 132 may be disposed on the first refractive layer 131 by a vacuum deposition method. The second refractive layer 132 may have a lower refractive index than the first refractive layer 131. The refractive index of the second refractive layer 132 may be in a range of about 1.20 to about 1.50, but is not limited thereto.

The second refractive layer 132 may include a lower refractive index oxide. For example, the low refractive index oxide may include at least one of a silicon resin, silica, and silicon dioxide (SiO₂).

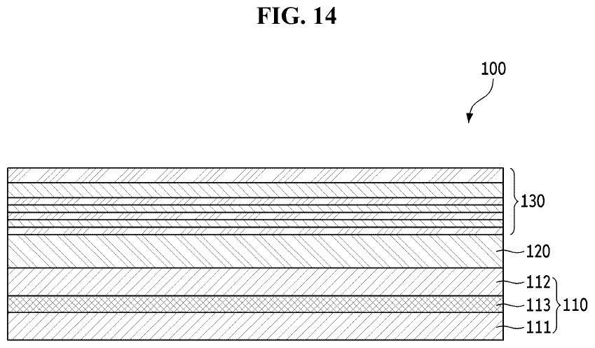

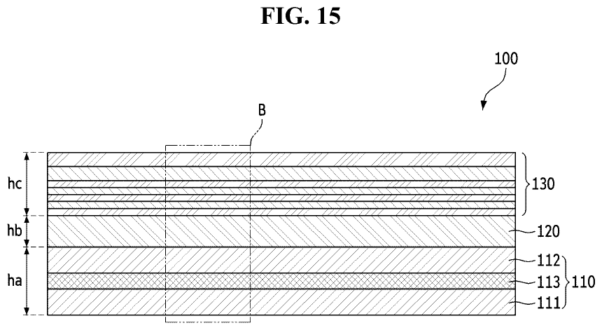

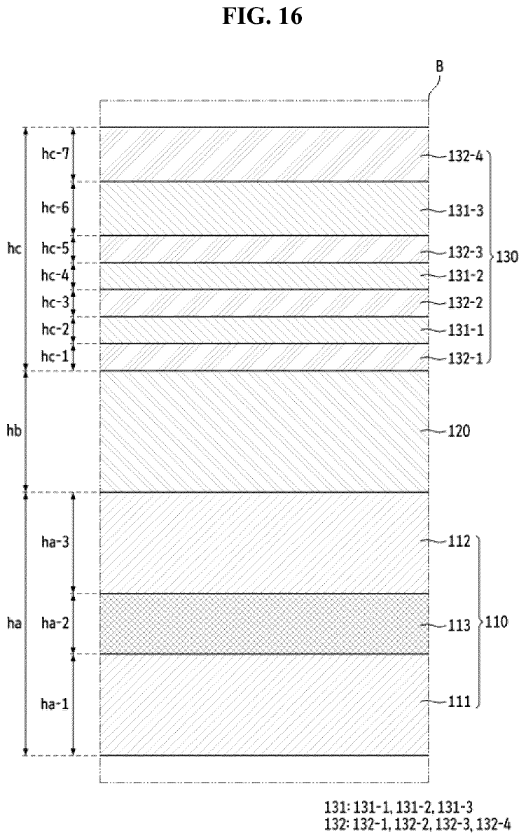

FIGS. 14 and 15 are schematic cross-sectional views illustrating a fourth embodiment of the anti-reflective film in the display device according to an embodiment of the disclosure. FIG. 16 is an enlarged schematic view of part B of FIG. 15.

Referring to FIGS. 14 to 16, an anti-reflective film 100 according to a fourth embodiment may include a protective member 110, a shock absorbing member 120, and a refractive member 130.

The protective member 110 may be disposed on the window member 200 (see FIG. 5). The protective member 110 may serve to protect the window member 200 from external shock (or force). The protective member 110 may have a higher strength than the window member 200. The protective member 110 may prevent an occurrence of micro-cracks or shape deformation such as being dented or pressed in the window member 200 due to point shock or surface shock provided from the outside. A thickness ha of the protective member 110 may be formed in a thickness range in which a repulsive force against the shape deformed by the display device 10 being folded does not increase.

The protective member 110 may include a first protective layer 111, a second protective layer 112, and a shock absorbing layer 113.

The first protective layer 111 may be provided as a hard coating layer disposed on the window member 200. The first protective layer 111 may include at least one of a urethane resin, an epoxy resin, an acrylic resin, and an acrylate resin. The first protective layer 111 may be disposed on the window member 200 by a coating method. For example, the first protective layer 111 may be disposed on the window member 200 using a method such as slot die coating, spin coating, etc. A thickness ha-1 of the first protective layer 111 may be the same as a thickness ha-3 of the second protective layer 112.

The second protective layer 112 may be provided as a hard coating layer disposed on the first protective layer 111. The second protective layer 112 may be disposed to be spaced apart from the first protective layer 111 in an upward direction so that the shock absorbing layer 113 may be disposed between the second protective layer 112 and the first protective layer 111. The second protective layer 112 may include at least one of a urethane resin, an epoxy resin, an acrylic resin, and an acrylate resin. The second protective layer 112 may be disposed on the shock absorbing layer 113 by a coating method. For example, the second protective layer 112 may be disposed on the shock absorbing layer 113 using a method such as slot die coating, spin coating, etc.

The shock absorbing layer 113 may be disposed between the first protective layer 111 and the second protective layer 112. The shock absorbing layer 113 may prevent the first protective layer 111 from being damaged in case that the display device 10 is folded. In some embodiments, even if a crack occurs in the second protective layer 112 due to folding of the display device 10, the shock absorbing layer 113 may absorb external shock (or force) caused by the crack and prevent the crack from occurring in the first protective layer 111.

The thickness ha-2 of the shock absorbing layer 113 may be thinner than each of the thickness ha-1 of the first protective layer 111 and the thickness ha-3 of the second protective layer 112. The thickness ha-2 of the shock absorbing layer 113 may be thinner than the thickness hb of the shock absorbing member 120.

The shock absorbing layer 113 may include at least one of polyethylene terephthalate (PET), acrylate, and urethane acrylate. The shock absorbing layer 113 may be attached onto the first protective layer 111 by an adhesive layer (not illustrated). The adhesive layer may include one of a pressure sensitive adhesive (PSA), an optical clear adhesive (OCA), and an optical clear resin (OCR). The shock absorbing layer 113 may be disposed on the first protective layer 111 by a coating method. For example, the shock absorbing layer 113 may be disposed on the first protective layer 111 using a method such as dip coating, slot die coating, or spin coating.

The shock absorbing member 120 may be disposed on the second protective layer 112. The shock absorbing member 120 may prevent the protective member 110 from being damaged in case that the display device 10 is folded. In some embodiments, even if a crack occurs in the refractive member 130 due to folding of the display device 10, the shock absorbing member 120 may absorb external shock (or force) caused by the crack and prevent the crack from occurring in the protective member 110. The thickness hb of the shock absorbing member 120 may be thinner than the thickness ha of the protective member 110 and a thickness hc of the refractive member 130.

The shock absorbing member 120 may include at least one of polyethylene terephthalate (PET), acrylate, and urethane acrylate. The shock absorbing member 120 may be attached onto the second protective layer 112 by an adhesive layer (not illustrated). The adhesive layer may include one of a pressure sensitive adhesive (PSA), an optical clear adhesive (OCA), and an optical clear resin (OCR). The shock absorbing member 120 may be disposed on the second protective layer 112 by a coating method. For example, the shock absorbing member 120 may be disposed on the second protective layer 112 using a method such as dip coating, slot die coating, or spin coating.

The refractive member 130 may be disposed on the shock absorbing member 120. The refractive member 130 may include a first refractive layer 131 and a second refractive layer 132 having different refractive indices. The first refractive layer 131 and the second refractive layer 132 may be provided in plural and may be alternately stacked.

The first refractive layer 131 may be disposed on the second refractive layer 132. The first refractive layer 131 may be disposed on the second refractive layer 132 by a vacuum deposition method. The first refractive layer 131 may have a higher refractive index than the second refractive layer 132. The refractive index of the first refractive layer 131 may be 1.70 to 2.80, but is not limited thereto.

The first refractive layer 131 may include a high refractive index oxide. For example, the high refractive index oxide may include at least one of titanium dioxide (TiO₂), zirconium dioxide (ZrO₂), lithium niobate (LiNbO₃), lithium tantalate (LiTaO₃), and lanthanum titanium (LaTiO₂).

The second refractive layer 132 may be disposed on the shock absorbing member 120 or on the first refractive layer 131. The second refractive layer 132 may be disposed on the shock absorbing member 120 or on the first refractive layer 131 by a vacuum deposition method. The second refractive layer 132 may have a lower refractive index than the first refractive layer 131. The refractive index of the second refractive layer 132 may be in a range of about 1.20 to about 1.50, but is not limited thereto.

The second refractive layer 132 may include a lower refractive index oxide. For example, the low refractive index oxide may include at least one of a silicon resin, silica, and silicon dioxide (SiO₂).

It will be described that multiple first refractive layers 131 and second refractive layers 132 are alternately stacked. One of multiple second refractive layers 132 may be disposed on the shock absorbing member 120, and another of multiple second refractive layers 132 may be disposed on the uppermost end of the refractive member 130. Multiple first refractive layers 131 may be disposed between the second refractive layers 132.

For example, the first refractive layer 131 may include a first_first refractive layer 131-1, a first_second refractive layer 131-2, and a first_third refractive layer 131-3, and the second refractive layer 132 may include a second_first refractive layer 132-1, a second_second refractive layer 132-2, a second_third refractive layer 132-3, and a second_fourth refractive layer 132-4.

The second_first refractive layer 132-1 may be disposed on the shock absorbing member 120, and the first_first refractive layer 131-1 may be disposed on the second_first refractive layer 132-1. The second_second refractive layer 132-2 may be disposed on the first_first refractive layer 131-1, and the first_second refractive layer 131-2 may be disposed on the second_second refractive layer 132-2. The second_third refractive layer 132-3 may be disposed on the first_second refractive layer 131-2, and the first_third refractive layer 131-3 may be disposed on the second_third refractive layer 132-3. The second_fourth refractive layer 132-4 may be disposed on the first_third refractive layer 131-3.

A thickness hc-2 of the first_first refractive layer 131-1, a thickness hc-4 of the first_second refractive layer 131-2, a thickness hc-1 of the second_first refractive layer 132-1, a thickness hc-3 of the second_second refractive layer 132-2, and a thickness hc-5 of the second_third refractive layer 132-3 may be the same.

A thickness of the first refractive layer 131 disposed on the uppermost end among multiple first refractive layers 131 and a thickness of the second refractive layer 132 disposed on the uppermost end among multiple second refractive layers 132 may be the same as each other. For example, a thickness hc-6 of the first_third refractive layer 131-3 and a thickness hc-7 of the second_fourth refractive layer 132-4 may be the same.

The thickness of the first refractive layer 131 disposed on the uppermost end among multiple first refractive layers 131 may be thicker than the thicknesses of other first refractive layers 131, and the thickness of the second refractive layer 132 disposed on the uppermost end among multiple second refractive layers 132 may be thicker than the thicknesses of other second refractive layers 132. For example, the thickness hc-6 of the first_third refractive layer 131-3 may be thicker than the thickness hc-2 of the first_first refractive layer 131-1 and the thickness hc-4 of the first_second refractive layer 131-2, and the thickness hc-7 of the second_fourth refractive layer 132-4 may be thicker than the thickness hc-1 of the second_first refractive layer 132-1, the thickness hc-3 of the second_second refractive layer 132-2, and the thickness hc-5 of the second_third refractive layer 132-3.

It is described in the embodiment that the refractive member 130 has three first refractive layers 131 and four second refractive layers 132 alternately stacked, but the disclosure is not limited thereto. The disclosure may include all cases in which one second refractive layer 132 is disposed on the shock absorbing member 120 and another second refractive layer 132 is disposed on the refractive member 130.

The display device according to one embodiment of the disclosure can be applied to various electronic devices. The electronic device according to the one embodiment of the disclosure includes the display device described above, and may further include modules or devices having additional functions in addition to the display device.

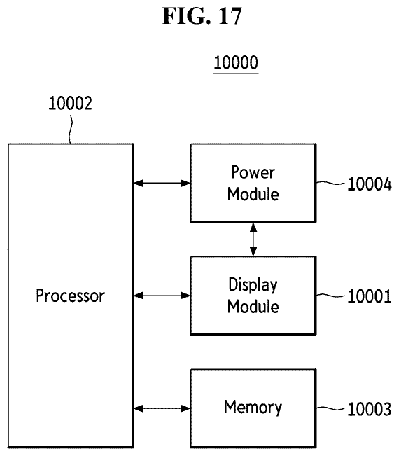

FIG. 17 is a schematic block diagram of an electronic device according to one embodiment of the disclosure.

Referring to FIG. 17, the electronic device 10000 according to one embodiment of the disclosure may include a display module 10001, a processor 10002, a memory 10003, and a power module 10004.

The processor 10002 may include at least one of a central processing unit (CPU), an application processor (AP), a graphic processing unit (GPU), a communication processor (CP), an image signal processor (ISP), and a controller.

The memory 10003 may store data information necessary for the operation of the processor 10002 or the display module 10001. In case that the processor 10002 executes an application stored in the memory 10003, an image data signal and/or an input control signal is transmitted to the display module 10001, and the display module 10001 can process the received signal and output image information through a display screen.

The power module 10004 may include a power supply module such as, for example a power adapter or a battery, and a power conversion module that converts the power supplied by the power supply module to generate power necessary for the operation of the electronic device 10000.

At least one of the components of the electronic device 10000 according to the one embodiment of the disclosure may be included in the display device according to the embodiments of the disclosure. Some modules of the individual modules functionally included in one module may be included in the display device, and other modules may be provided separately from the display device. For example, the display device may include the display module 10001, and the processor 10002, the memory 10003, and the power module 10004 may be provided in the form of other devices within the electronic device 10000 other than the display device.

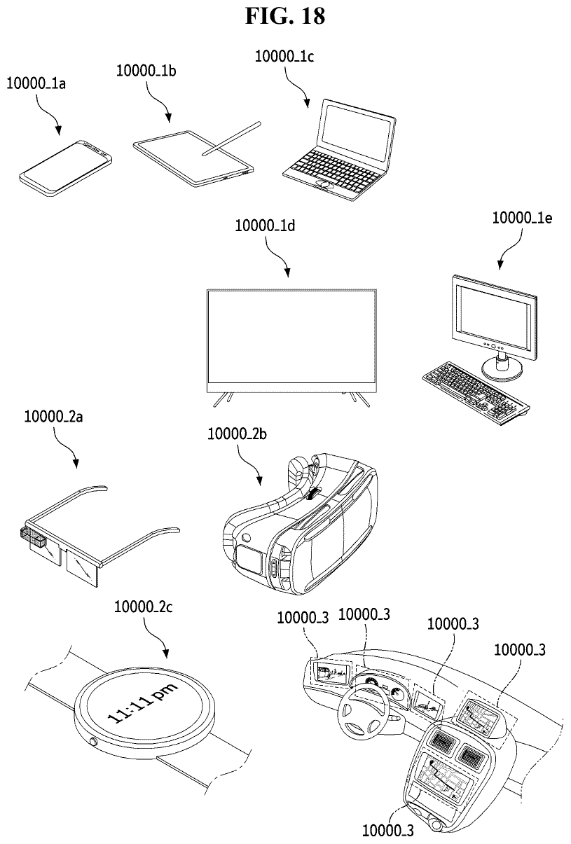

FIG. 18 is a schematic diagram of an electronic device according to various embodiments of the disclosure.

Referring to FIG. 18, various electronic devices to which display devices according to embodiments of the disclosure are applied may include not only image display electronic devices such as a smart phone 10000_1a, a tablet PC (personal computer) 10000_1b, a laptop 10000_1c, a TV 10000_1d, and a desk monitor 10000_1e, but also wearable electronic devices including display modules such as, for example smart glasses 10000_2a, a head mounted display 10000_2b, and a smart watch 10000_2c, and vehicle electronic devices 10000_3 including display modules such as a CID (Center Information Display) and a room mirror display arranged on a dashboard, center fascia, and dashboard of an automobile.

It should be understood, however, that the aspects and features of embodiments of the disclosure are not restricted to the one set forth herein. The above and other aspects of the disclosure will become more apparent to one of ordinary skill in the art to which the disclosure pertains by referencing the claims, with equivalents thereof to be included therein.

What is claimed is:

1. An anti-reflective film comprising:
a protective member;
a refractive member disposed on a surface of the protective member; and
a shock absorbing member disposed between the protective member and the refractive member.

2. The anti-reflective film of claim 1, wherein the refractive member includes a first refractive layer and a second refractive layer,
the first refractive layer is disposed on the shock absorbing member, and
the second refractive layer is disposed on the first refractive layer.

3. The anti-reflective film of claim 2, wherein the first refractive layer has a higher refractive index than the second refractive layer.

4. The anti-reflective film of claim 1, wherein the refractive member includes a first refractive layer and a second refractive layer, and
the first refractive layer and the second refractive layer are provided in plural and are alternately stacked.

5. The anti-reflective film of claim 4, wherein one of the plurality of second refractive layers is disposed on the shock absorbing member, and
another of the plurality of second refractive layers is disposed at an uppermost end of the refractive member.

6. The anti-reflective film of claim 4, wherein thicknesses of the first refractive layer disposed at an uppermost end among the plurality of first refractive layers and the second refractive layer disposed at an uppermost end among the plurality of second refractive layers are substantially the same as each other.

7. The anti-reflective film of claim 4, wherein a thickness of a first refractive layer disposed at an uppermost end among the plurality of first refractive layers is thicker than thicknesses of other first refractive layers, and
a thickness of a second refractive layer disposed at an uppermost end among the plurality of second refractive layers is thicker than thicknesses of other second refractive layers.

8. The anti-reflective film of claim 4, wherein the first refractive layer has a higher refractive index than the second refractive layer.

9. The anti-reflective film of claim 1, wherein a thickness of the shock absorbing member is thinner than thicknesses of the protective member and the refractive member.

10. The anti-reflective film of claim 1, wherein the shock absorbing member includes at least one of polyethylene terephthalate (PET), acrylate, and urethane acrylate.

11. The anti-reflective film of claim 1, wherein the protective member includes a first protective layer, a second protective layer, and a shock absorbing layer, and
the shock absorbing layer is disposed between the first protective layer and the second protective layer.

12. The anti-reflective film of claim 11, wherein a thickness of the shock absorbing layer is thinner than thicknesses of the first protective layer and the second protective layer.

13. The anti-reflective film of claim 11, wherein a thickness of the shock absorbing layer is thinner than a thickness of the shock absorbing member.

14. The anti-reflective film of claim 11, wherein the shock absorbing layer includes at least one of polyethylene terephthalate (PET), acrylate, and urethane acrylate.

15. A display device comprising:
a display panel;
a window member disposed on the display panel; and
an anti-reflective film disposed on a surface of the window member,
wherein the anti-reflective film includes:
a protective member disposed on the surface of the window member;
a refractive member disposed on a surface of the protective member; and
a shock absorbing member disposed between the protective member and the refractive member.

16. The display device of claim 15, wherein the refractive member includes a first refractive layer and a second refractive layer,
the first refractive layer is disposed on the shock absorbing member, and
the second refractive layer is disposed on the first refractive layer.

17. The display device of claim 16, wherein the first refractive layer has a higher refractive index than the second refractive layer.

18. The display device of claim 15, wherein the refractive member includes a first refractive layer and a second refractive layer, and
the first refractive layer and the second refractive layer are provided in plural and are alternately stacked.

19. The display device of claim 18, wherein one of the plurality of second refractive layers is disposed on the shock absorbing member, and
another of the plurality of second refractive layers is disposed at an uppermost end of the refractive member.

20. An electronic device comprising:
a display panel;
a window member disposed on the display panel; and
an anti-reflective film disposed on a surface of the window member,
wherein the anti-reflective film includes:
a protective member disposed on the surface of the window member;
a refractive member disposed on a surface of the protective member; and
a shock absorbing member disposed between the protective member and the refractive member.
